(19) United States
(12) Patent Application Publication
(10) Pub. No.: US 2016/0172274 A1
(43) Pub. Date: Jun. 16, 2016

(54) SYSTEM, APPARATUS, AND METHOD FOR SEMICONDUCTOR PACKAGE GROUNDS

(71) Applicant: Qualcomm Incorporated, San Diego, CA (US)

(72) Inventors: Jung Ho YOON, San Diego, CA (US); Young Kyu SONG, San Diego, CA (US); Uei-Ming JOW, San Diego, CA (US); Jong-Hoon LEE, San Diego, CA (US); Xiaonan ZHANG, San Diego, CA (US)

(21) Appl. No.: 14/572,760

(22) Filed: Dec. 16, 2014

(51) Int. Cl. H01L 23/495; H01L 21/48; H01L 23/66; H01L 23/522

(52) U.S. Cl. CPC H01L 23/49541; H01L 23/49524; H01L 23/49568; H01L 23/5226; H01L 21/4825; H01L 23/66; H01L 2223/6605

(57) ABSTRACT

A semiconductor package according to some examples may include a first portion of a support plate configured as an RF signal connection, a semiconductor die thermally coupled to a second portion of the support plate to dissipate heat, a first redistribution layer positioned in close proximity to a second redistribution layer to capacitively couple the first redistribution layer to the second redistribution layer, a first via extending between the first portion and the first redistribution layer, and a second via in close proximity to the first via to capacitively couple the second via to the first via.

### FIELD OF DISCLOSURE

This disclosure relates generally to semiconductor ground planes, and more specifically, but not exclusively, to semiconductor ground planes with associated signal vias.

### BACKGROUND

As semiconductor packages become more complex, they become more prone to warpage. To address this problem, conventional semiconductor packages use a metal stiffener to provide mechanical support for the package and to help prevent or reduce warpage. However, the metal stiffener increases the package profile without providing additional functionality or benefits. In addition, RF semiconductor packages are subject to signal degradation and insertion loss because of the inductance created by the RF signals traversing the signal pathways or redistribution layers in the semiconductor package.

Accordingly, there are long-felt industry needs for methods that improve upon conventional methods including the improved methods and apparatus provided hereby.

The inventive features that are characteristic of the teachings, together with further features and advantages, are better understood from the detailed description and the accompanying figures. Each of the figures is provided for the purpose of illustration and description only, and does not limit the present teachings.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

Some examples of the disclosure are directed to systems, apparatus, and methods for an increase in signal integrity with a guided via connection, a lower insertion loss with a guided via connection, increased isolation between signal paths, increased input/output (I/O) pin counts, increased heat flow form a die to a support plate, and the ability to add

SMD components on a top of a semiconductor package.

In some examples of the disclosure, the system, apparatus, and method may include a semiconductor die attached to a support plate; a first portion of the support plate configured as a signal connection; a first redistribution layer positioned horizontally above the semiconductor die and coupled to the semiconductor die forming a first signal path; a first via extending vertically between the first portion and the first redistribution layer coupling the signal connection to the first signal path; a second portion of the support plate configured as a ground plane; a second redistribution layer positioned horizontally above the semiconductor die and coupled to the semiconductor die forming a second signal path; and a second via extending vertically between the second portion and the second redistribution layer coupling the ground plane to the second signal path.

In some examples of the disclosure, the system, apparatus, and method may include a die attached and thermally coupled to a metal plate; a first portion of the metal plate configured as a RF signal connection; a second portion of the metal plate configured as a ground plane; a signal via coupling the RF signal connection to a first redistribution layer; and a ground via coupling the ground plane to a second redistribution layer.

In some examples of the disclosure, the system, apparatus, and method may include attaching a semiconductor die to a metal support plate with a thermal interface material that thermally couples the semiconductor die to the metal support plate; encapsulating the semiconductor die and the metal support plate with a molding material; separating the metal support plate into a first portion and a second portion physically separate from the first portion; forming a plurality of first vias extending vertically upward from the first portion to a surface of the molding material; forming a plurality of second vias extending vertically upward from the second portion to the surface of the molding material; forming a second redistribution layer on the surface of the molding material and coupled to the plurality of second vias; forming a second mold layer on the surface of the molding material; and forming a first redistribution layer on a surface of the second mold layer and coupled to the plurality of first vias.

In some examples of the disclosure, the system, apparatus, and method may include attaching a semiconductor die to a support plate to thermally couple the semiconductor die to the support plate; patterning the support plate into a first portion and a second portion electrically isolated from the first portion; forming a signal via extending vertically upward from the first portion; forming a ground via extending vertically upward from the second portion, the ground via electrically isolated from the signal via and wherein a proximity of the ground via to the signal via capacitively couples the ground via to the signal via; forming a first redistribution layer above the first portion and coupled to the signal via; and forming a second redistribution layer above the second portion and coupled to the ground via, wherein a proximity of the second redistribution layer to the first redistribution layer capacitively couples the second redistribution layer to the first redistribution layer.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates an exemplary processor in accordance with some examples of the disclosure.

FIG. 2 illustrates exemplary user equipment (UE) in accordance with some examples of the disclosure.

FIG. 3 illustrates a side view of an exemplary semiconductor package in accordance with some examples of the disclosure.

FIG. 4 illustrates a bottom view of a patterned support plate in accordance with some examples of the disclosure.

FIGS. 5A-F illustrate side views of a partial process flow for the manufacture of an exemplary semiconductor package in accordance with some examples of the disclosure.

FIG. 6 illustrates a side view of an exemplary semiconductor package with surface mounted devices in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein advantageously address the long-felt industry needs, as well as other previously unidentified needs, and mitigate shortcomings of the conventional methods, apparatus, and systems.

Various aspects are disclosed in the following description and related drawings to show specific examples relating to the disclosure. Alternate examples will be apparent to those skilled in the pertinent art upon reading this disclosure, and may be constructed and practiced without departing from the scope or spirit of the disclosure. Additionally, well-known elements will not be described in detail or may be omitted so as to not obscure the relevant details of the aspects and examples disclosed herein.

The word “exemplary” is used herein to mean “serving as an example, instance, or illustration.” Any details described herein as “exemplary” is not necessarily to be construed as preferred or advantageous over other examples. Likewise, the term “examples” does not require that all examples include the discussed feature, advantage or mode of operation. Use of the terms “in one example,” “an example,” “in one feature,” and/or “a feature” in this specification does not necessarily refer to the same feature and/or example. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples only and is not intended to be limiting of examples of the disclosure. As used herein, the singular forms “a,” “an,” and “the” are intended to include the plural forms as well, unless the context clearly indicates otherwise. It will be further understood that the terms “comprises”, “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element. Coupling and/or connection between the elements can be physical, logical, or a combination thereof. As employed herein, elements can be “connected” or “coupled” together, for example, by using one or more wires, cables, and/or printed electrical connections, as well as by using electromagnetic energy. The electromagnetic energy can have wavelengths in the radio frequency region, the microwave region and/or the optical (both visible and invisible) region. These are several non-limiting and non-exhaustive examples.

It should be understood that the term “signal” can include any signal such as a data signal, audio signal, video signal, multimedia signal, analog signal, and/or digital signal. Information and signals can be represented using any of a variety of different technologies and techniques. For example, data, an instruction, a process step, a command, information, a signal, a bit, and/or a symbol described in this description can be represented by a voltage, a current, an electromagnetic wave, a magnetic field and/or particle, an optical field and/or particle, and any combination thereof.

Any reference herein to an element using a designation such as “first,” “second,” and so forth does not limit the quantity and/or order of those elements. Rather, these designations are used as a convenient method of distinguishing between two or more elements and/or instances of an element. Thus, a reference to first and second elements does not mean that only two elements can be employed, or that the first element must necessarily precede the second element. Also, unless stated otherwise, a set of elements can comprise one or more elements. In addition, terminology of the form “at least one of: A, B, or C” used in the description or the claims can be interpreted as “A or B or C or any combination of these elements.”

Further, many examples are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the disclosure may be embodied in a number of different forms, all of which have been contemplated to be within the scope of the claimed subject matter. In addition, for each of the examples described herein, the corresponding form of any such examples may be described herein as, for example, “logic configured to” perform the described action.

In this description, certain terminology is used to describe certain features. The term “mobile device” can describe, and is not limited to, a mobile phone, a mobile communication device, a pager, a personal digital assistant, a personal information manager, a mobile hand-held computer, a laptop computer, a wireless device, a wireless modem, and/or other types of portable electronic devices typically carried by a person and/or having communication capabilities (e.g., wireless, cellular, infrared, short-range radio, etc.). Further, the terms “user equipment” (UE), “mobile terminal,” “mobile device,” and “wireless device,” can be interchangeable.

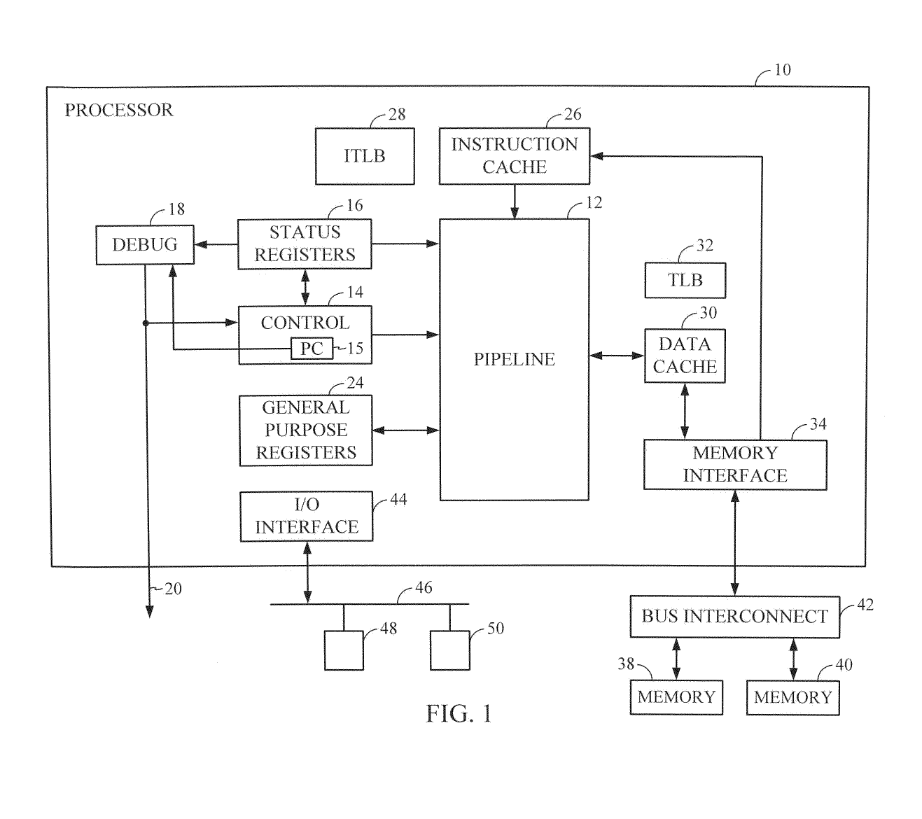

FIG. 1 depicts a functional block diagram of an exemplary processor 10, such as an ASIC 208 (see below) configured to incorporate features of the improved data decompression. Processor 10 executes instructions in an instruction execution pipeline 12 according to control logic 14. Control logic 14 maintains a Program Counter (PC) 15, and sets and clears bits in one or more status registers 16 to indicate, e.g., the current instruction set operating mode, information regarding the results of arithmetic operations and logical comparisons (zero, carry, equal, not equal), and the like. In some examples, pipeline 12 may be a superscalar design, with multiple, parallel pipelines. Pipeline 12 may also be referred to as an execution unit. A General Purpose Register (GPR) file 20 provides a list of general purpose registers 24 accessible by pipeline 12, and comprising the top of the memory hierarchy.

Processor 10, which executes instructions from at least two instruction sets in different instruction set operating modes, additionally includes a debug circuit 18, operative to compare, upon the execution of each instruction, at least a predetermined target instruction set operating mode to the current instruction set operating mode, and to provide an indication of a match between the two.

Pipeline 12 fetches instructions from an instruction cache (I-cache) 26, with memory address translation and permissions managed by an Instruction-side Translation Lookaside Buffer (ITLB) 28. Data is accessed from a data cache (D-cache) 30, with memory address translation and permissions managed by a main Translation Lookaside Buffer (TLB) 32. In various examples, ITLB 28 may comprise a copy of part of TLB 32. Alternatively, ITLB 28 and TLB 32 may be integrated. Similarly, in various examples of processor 10, I-cache 26 and D-cache 30 may be integrated, or unified. Further, I-cache 26 and D-cache 30 may be L1 caches. Misses in I-cache 26 and/or D-cache 30 cause an access to main (off-chip) memory 38, 40 by a memory interface 34. Memory interface 34 may be a master input to a bus interconnect 42 implementing a shared bus to one or more memory devices 38, 40 that may incorporate the improved data decompression in accordance with some examples of the disclosure. Additional master devices (not shown) may additionally connect to bus interconnect 42.

Processor 10 may include input/output (I/O) interface 44, which may be a master device on a peripheral bus, across which I/O interface 44 may access various peripheral devices 48, 50 via bus 46. Those of skill in the art will recognize that numerous variations of processor 10 are possible. For example, processor 10 may include a second-level (L2) cache for either or both I and D caches 26, 30. In addition, one or more of the functional blocks depicted in processor 10 may be omitted from a particular example. Other functional blocks that may reside in processor 10, such as a JTAG controller, instruction pre-decoder, branch target address cache, and the like are not germane to a description of the present disclosure, and are omitted for clarity.

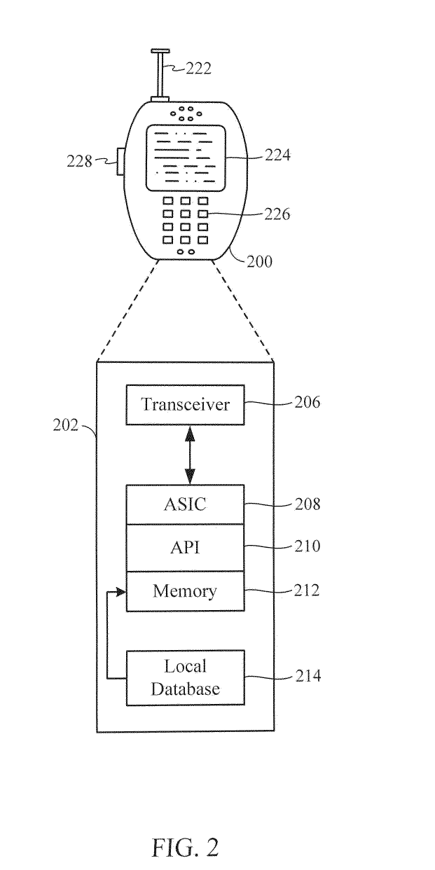

Referring to FIG. 2, a system 100 that includes a UE 200, (here a wireless device), such as a cellular telephone, which has a platform 202 that can receive and execute software applications, data and/or commands transmitted from a radio access network (RAN) that may ultimately come from a core network, the Internet and/or other remote servers and networks. Platform 202 can include transceiver 206 operably coupled to an application specific integrated circuit (“ASIC” 208), or other processor, microprocessor, logic circuit, or other data processing device. ASIC 208 or other processor executes the application programming interface (“API”) 210 layer that interfaces with any resident programs in memory 212 of the wireless device. Memory 212 can be comprised of read-only or random-access memory (RAM and ROM), EEPROM, flash cards, or any memory common to computer platforms. Platform 202 also can include local database 214 that can hold applications not actively used in memory 212. Local database 214 is typically a flash memory cell, but can be any secondary storage device as known in the art, such as magnetic media, EEPROM, optical media, tape, soft or hard disk, or the like. Internal platform 202 components can also be operably coupled to external devices such as antenna 222, display 224, push-to-talk button 228 and keypad 226 among other components, as is known in the art.

Accordingly, an example of the disclosure can include a UE including the ability to perform the functions described herein. As will be appreciated by those skilled in the art, the various logic elements can be embodied in discrete elements, software modules executed on a processor or any combination of software and hardware to achieve the functionality disclosed herein. For example, ASIC 208, memory 212, API 210 and local database 214 may all be used cooperatively to load, store and execute the various functions disclosed herein and thus the logic to perform these functions may be distributed over various elements. Alternatively, the functionality could be incorporated into one discrete component. Therefore, the features of UE 200 in FIG. 2 are to be considered merely illustrative and the disclosure is not limited to the illustrated features or arrangement.

The wireless communication between UE 200 and the RAN can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE) or other protocols that may be used in a wireless communications network or a data communications network. Accordingly, the illustrations provided herein are not intended to limit the examples of the disclosure and are merely to aid in the description of aspects of examples of the disclosure.

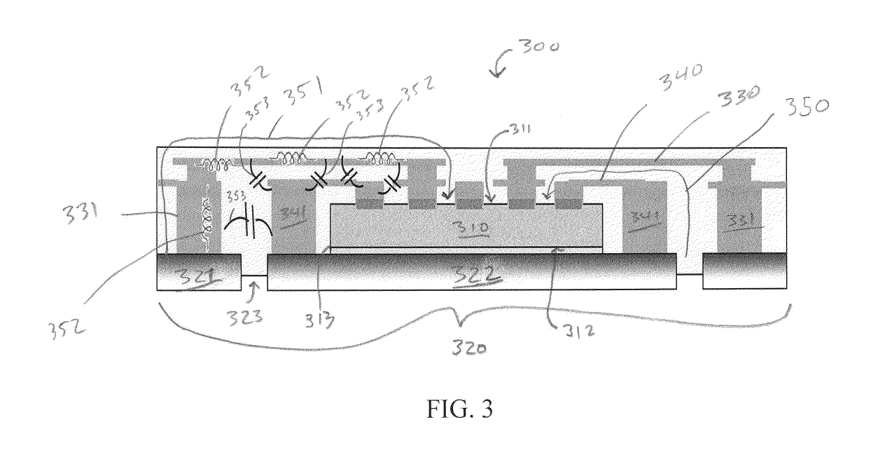

FIG. 3 illustrates a side view of an exemplary semiconductor package in accordance with some examples of the disclosure. As shown in FIG. 3, a semiconductor package 300 may include a semiconductor die 310, a support plate 320 attached to a backside of the semiconductor die 310, a first redistribution layer 330, a plurality of first vias 331 extending between the support plate 320 and the first redistribution layer 330, a second redistribution layer 340, and a plurality of second vias 341 extending between the support plate 320 and the second redistribution layer 340. The semiconductor die 310 may be any type of semiconductor die or chip, such as a logic die or a memory die. The semiconductor die 310 may include an active side 311 facing away from the support plate 320 and a backside 312 facing towards the support plate 320. The semiconductor die 310 may be attached to the support plate 320 by a thermally conductive adhesive 313 between the support plate 320 and the backside 312, such as thermal interface material. The thermally conductive adhesive 313 allows the heat generated by the semiconductor die 310 to be transferred to the support plate 320 for dissipation and storage.

The support plate 320 may be a metal stiffener or carrier that provides mechanical support and may include a first portion 321 configured or patterned as RF signal connections or pads and a second portion 322 configured or patterned as a ground plane in the center of the support plate 320. The first portion 321 and the second portion 322 are electrically isolated from one another by a gap 323 or insulation material (not shown). The semiconductor die 310 may be attached to the second portion 322 and centered thereon.

The first redistribution layer 330 provides a signal path 351 for RF signals through the semiconductor package 300. The first redistribution layer 330 may be coupled to the plurality of first vias 331 that extend from the first portion 321 to the first redistribution layer 330 and provide a signal path 351 from the first portion 321 signal connection pads through the first vias 331 and the first redistribution layer 330 to the active side 311 of the semiconductor die 310.

The second redistribution layer 340 is separated and spaced from the first redistribution layer 330. The second redistribution layer 340 may be coupled to the plurality of second vias 341 that extend from the second portion 322 to the second redistribution layer 340 and provide a ground path 350 from the second portion 322 ground plane through the plurality of second vias 341 and the second redistribution layer 340 to the active side 311 of the semiconductor die 310. By having a ground path 350 parallel but separate from the RF signal path 351, the RF signal inductance 352 created by the RF signal traveling along the RF signal path 351 from the connection pad to the semiconductor die can be reduced due to the capacitive coupling 353 between the parallel first 331 and second 341 vias as well as the parallel first distribution layer 330 and second distribution layer 340.

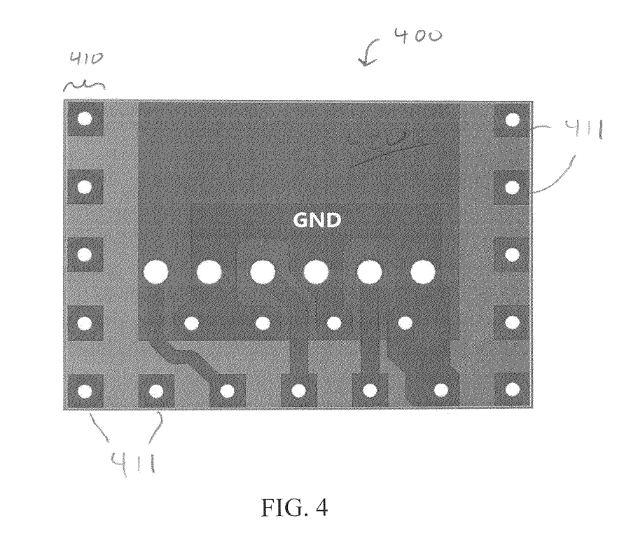

FIG. 4 illustrates a bottom view of a patterned support plate in accordance with some examples of the disclosure. As shown in FIG. 4, a patterned support plate 400 may include a first portion 410 and a second portion 420. The first portion 410 may include a plurality of signal connection pads 411 that may provide a connection pad for RF signal connections. The second portion 420 may be coupled to a ground to create a ground plane for a semiconductor package. By having the RF signal path and the ground path in close proximity, the RF signal insertion loss and the inductance on the RF signal path may be reduced while the isolation between the ground signals and the RF signals may be increased.

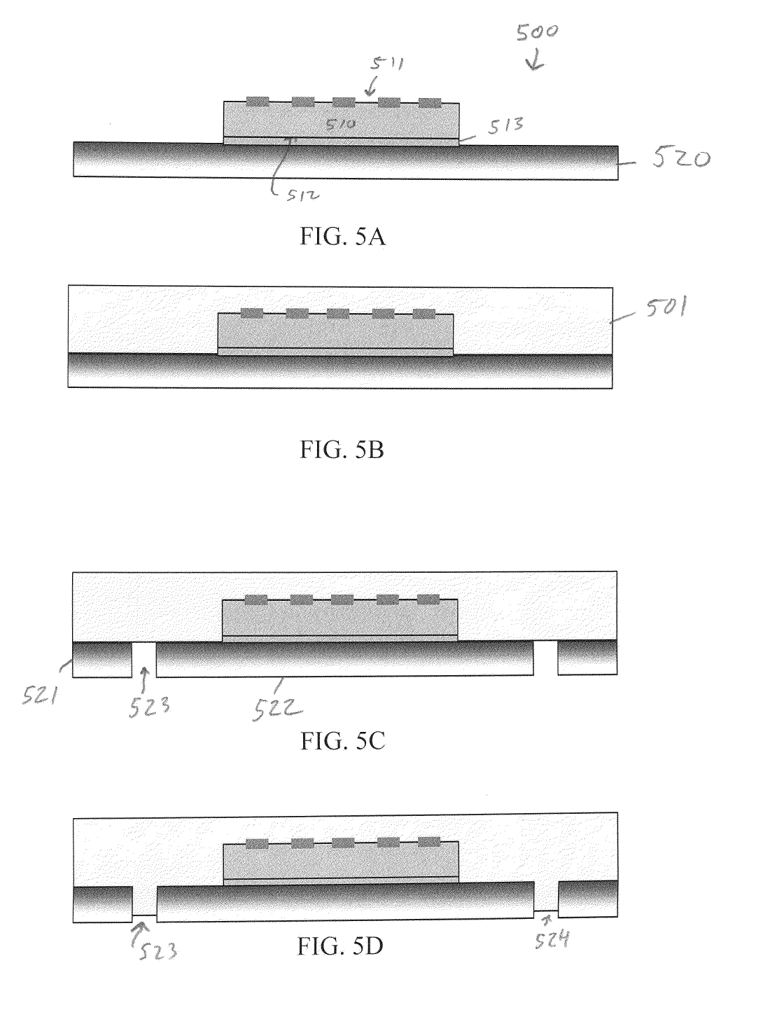

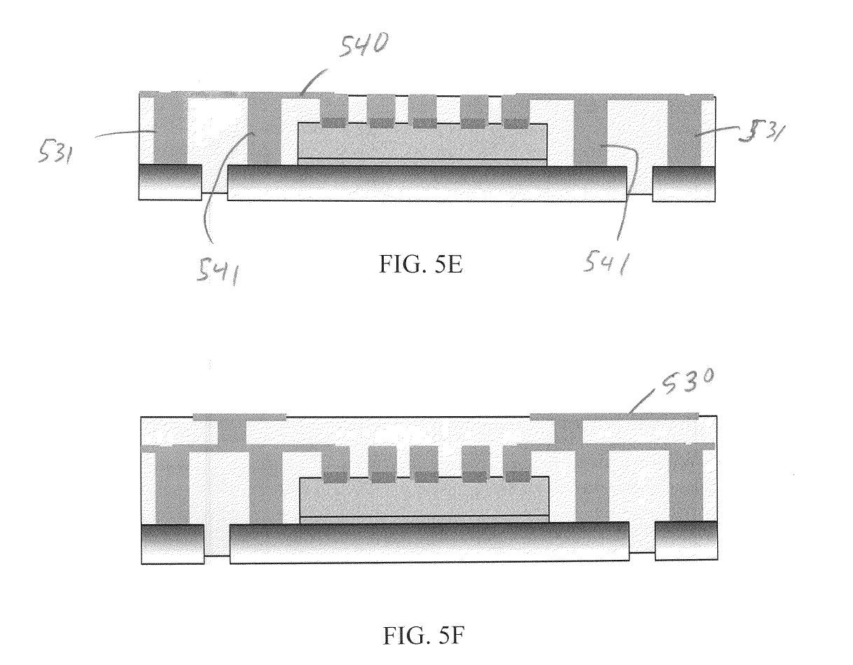

FIGS. 5A-F illustrate side views of a partial process flow for the manufacture of an exemplary semiconductor package in accordance with some examples of the disclosure. The partial process flow begins as shown in FIG. 5A wherein a semiconductor package 500 begins formation by placing a semiconductor die 510 on an thermally conductive adhesive layer 513 to attach the semiconductor die 510 to a support plate (stiffener or carrier) 520. The backside 512 of the semiconductor die 510 is place on the adhesive layer 513 so that the backside 512 is facing towards the support plate 520 and an active side 511 of the semiconductor die 510 is facing away from the support plate 520. The process continues in FIG. 5B where an encapsulation molding 501 is place over the current structure to encapsulate the semiconductor die 510 on a top surface of the support plate 520.

The process continues in FIG. 5C where the bottom surface of the support place 520 is patterned to create a first portion 521 and a second portion 522 electrically isolated from the first portion 521 by a gap 523. The bottom surface of the support plate 520 may be patterned in a number of different configurations, such as in a land grid array (LGA) configuration for mating to a printed circuit board or the like. The process continues in FIG. 5D where the gap 523 is filled with filling material to increase the isolation between the first portion 521 and the second portion 522.

The process continues in FIG. 5E where a plurality of first vias 531, a plurality of second vias 541, and a second redistribution layer 540 are formed. The plurality of first vias 531 extend from the first portion 521 vertically upward towards the surface of molding 501 and are composed of electrically conductive material. The plurality of second vias 541 extend vertically upward towards the second redistribution layer 540 and are composed of electrically conductive material. The second redistribution layer 540 extends from a top of the second vias horizontally inward towards the semiconductor die 510 and is composed of electrically conductive material that will eventually be coupled to ground through the second portion 522.

The process continues in FIG. 5F, where additional molding material is added to the top of the semiconductor package 500 and an electrically conductive first redistribution layer 530 is formed vertically above the second redistribution layer 540 extending from the first vias 531 horizontally inward towards the semiconductor die 510. While the figures show connections between the first redistribution layer 530 and the second redistribution layer 540, these connections will be broken/removed prior to completion such that the first redistribution layer 530 and the second redistribution layer 540 are physically separate from one another.

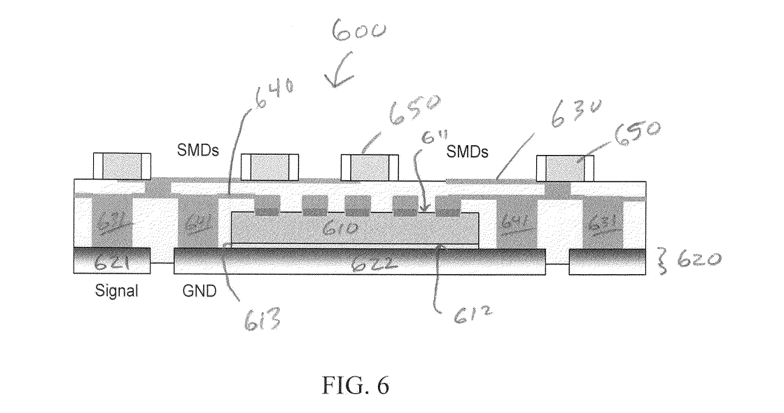

FIG. 6 illustrates a side view of an exemplary semiconductor package with surface mounted devices in accordance with some examples of the disclosure. As shown in FIG. 6, a semiconductor package 600 may include a semiconductor die 610, a support plate 620 attached to a backside of the semiconductor die 610, a first redistribution layer 630, a plurality of first vias 631 extending between the support plate 620 and the first redistribution layer 630, a second redistribution layer 640, a plurality of second vias 641 extending between the support plate 620 and the second redistribution layer 640, and a plurality of surface mounted devices (SMDs) 650. The semiconductor die 610 may be any type of semiconductor die or chip, such as a logic die or a memory die. The semiconductor die 610 may include an active side 611 facing away from the support plate 620 and a backside 612 facing towards the support plate 620. The semiconductor die 610 may be attached to the support plate 620 by a thermally conductive adhesive 613 between the support plate 620 and the backside 612, such as thermal interface material. The thermally conductive adhesive 613 allows the heat generated by the semiconductor die 610 to be transferred to the support plate 620 for dissipation and storage. The surface mounted devices 650 may be a number of different devices including, but not limited to, diodes, rectifier, transistors, etc.

The support plate 620 may be a metal stiffener or carrier that provides mechanical support and may include a first portion 621 configured or patterned as RF signal connections or pads and a second portion 622 configured or patterned as a ground plane in the center of the support plate 620. The first portion 621 and the second portion 622 are electrically isolated from one another by a gap 623 or insulation material (not shown). The semiconductor die 610 may be attached to the second portion 622 and centered thereon.

The first redistribution layer 630 provides a signal path for RF signals through the semiconductor package 600. The first redistribution layer 630 may be coupled to the plurality of first vias 631 that extend from the first portion 621 to the first redistribution layer 630 and provide a signal path from the first portion 621 signal connection pads through the first vias 631 and the first redistribution layer 630 to the active side 611 of the semiconductor die 610.

The second redistribution layer 640 is separated and spaced from the first redistribution layer 630. The second redistribution layer 640 may be coupled to the plurality of second vias 641 that extend from the second portion 622 to the second redistribution layer 640 and provide a ground path from the second portion 622 ground plane through the plurality of second vias 641 and the second redistribution layer 640 to the active side 611 of the semiconductor die 610. By having a ground path parallel but separate from the RF signal path, the RF signal inductance created by the RF signal traveling along the RF signal path from the connection pad to the semiconductor die can be reduced due to the capacitive coupling between the parallel first and second vias as well as the parallel first distribution layer and second distribution layer.

It should be understood that although the description above mentions a metal stiffener, substitute materials can be used in place of metal. The substitute materials can include metal alloys and similar materials that provide mechanical support as well as a ground or connection for signals.

Examples of the methods, apparatus, and systems described herein can be used in a number of applications, such as wafer level packages and RF fan out land grid array semiconductor packages. Further applications should be readily apparent to those of ordinary skill in the art.

Nothing stated or illustrated depicted in this application is intended to dedicate any component, step, feature, benefit, advantage, or equivalent to the public, regardless of whether the component, step, feature, benefit, advantage, or the equivalent is recited in the claims.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the examples disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The methods, sequences and/or algorithms described in connection with the examples disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

The various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

Although some aspects have been described in connection with a device, it goes without saying that these aspects also constitute a description of the corresponding method, and so a block or a component of a device should also be understood as a corresponding method step or as a feature of a method step. Analogously thereto, aspects described in connection with or as a method step also constitute a description of a corresponding block or detail or feature of a corresponding device. Some or all of the method steps can be performed by a hardware apparatus (or using a hardware apparatus), such as, for example, a microprocessor, a programmable computer or an electronic circuit. In some examples, some or a plurality of the most important method steps can be performed by such an apparatus.

The examples described above merely constitute an illustration of the principles of the present disclosure. It goes without saying that modifications and variations of the arrangements and details described herein will become apparent to other persons skilled in the art. Therefore, it is intended that the disclosure be restricted only by the scope of protection of the appended patent claims, rather than by the specific details presented on the basis of the description and the explanation of the examples herein.

In the detailed description above it can be seen that different features are grouped together in examples. This manner of disclosure should not be understood as an intention that the claimed examples require more features than are explicitly mentioned in the respective claim. Rather, the situation is such that inventive content may reside in fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or a plurality of claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods disclosed in the description or in the claims can be implemented by a device comprising means for performing the respective steps or actions of this method.

Furthermore, in some examples, an individual step/action can be subdivided into a plurality of sub-steps or contain a plurality of sub-steps. Such sub-steps can be contained in the disclosure of the individual step and be part of the disclosure of the individual step.

While the foregoing disclosure shows illustrative examples of the disclosure, it should be noted that various changes and modifications could be made herein without departing from the scope of the disclosure as defined by the appended claims. The functions, steps and/or actions of the method claims in accordance with the examples of the disclosure described herein need not be performed in any particular order. Furthermore, although elements of the disclosure may be described or claimed in the singular, the plural is contemplated unless limitation to the singular is explicitly stated.

A complete listing of the claims, including current amendments (if any), is as follows:

1. A semiconductor package, comprising:
a semiconductor die attached to a support plate;
a first portion of the support plate configured as a signal connection;
a first redistribution layer positioned horizontally above the semiconductor die and coupled to the semiconductor die forming a first signal path;
a first via extending vertically between the first portion of the support plate and the first redistribution layer coupling the first portion of the support plate to the first redistribution layer;
a second portion of the support plate configured as a ground plane;
a second redistribution layer positioned horizontally above the semiconductor die and coupled to the semiconductor die forming a second signal path; and
a second via extending vertically between the second portion of the support plate and the second redistribution layer coupling the second portion of the support plate to the second redistribution layer.

2. The semiconductor package of claim 1, wherein the first redistribution layer is adjacent to and separate from the second redistribution layer and the first signal path forms a transmission line for a RF signal.

3. The semiconductor package of claim 2, wherein a proximity of the first redistribution layer to the second redistribution layer capacitively couples the first redistribution layer to the second redistribution layer to reduce inductive coupling of the RF signal in the first redistribution layer.

4. The semiconductor package of claim 3, wherein a proximity of the first via to the second via capacitively couples the first via to the second via to reduce inductive coupling of the RF signal in the first via.

5. The semiconductor package of claim 4, wherein the second portion of the support plate is thermally coupled to the semiconductor die for dissipation of heat generated by the semiconductor die.

6. The semiconductor package of claim 5, further comprising a surface mounted device coupled to the first redistribution layer.

7. The semiconductor package of claim 6, wherein the support plate is configured in a fan out land grid array pattern.

8. The semiconductor package of claim 7, wherein the first portion of the support plate is physically separate from the second portion of the support plate to electrically isolate the first signal path from the second signal path.

9. The semiconductor package of claim 8, wherein the support plate is metal.

10. The semiconductor package of claim 9, wherein the first portion of the support plate is configured as a plurality of signal connection pads.

11. The semiconductor package of claim 10, further comprising a thermal interface material positioned between the semiconductor die and the second portion of the support plate to adhere the semiconductor die to the support plate.

12. The semiconductor package of claim 11, wherein the semiconductor package is integrated into one of a mobile phone, a mobile communication device, a pager, a personal digital assistant, a personal information manager, a mobile hand-held computer, a laptop computer, a wireless device, or a wireless modem.

13. A radio frequency (RF) semiconductor package, comprising:
a die attached and thermally coupled to a metal plate;
a first portion of the metal plate configured as a RF signal connection;
a second portion of the metal plate configured as a ground plane;
a signal via coupling the first portion of the metal plate to a first redistribution layer; and
a ground via coupling the second portion of the metal plate to a second redistribution layer.

14. The RF semiconductor package of claim 13, wherein the first redistribution layer is adjacent to the second redistribution layer and the first redistribution layer forms a transmission line for the RF signal connection.

15. The RF semiconductor package of claim 14, wherein a proximity of the first redistribution layer to the second redistribution layer capacitively couples the first redistribution layer to the second redistribution layer to reduce inductive coupling of the RF signal in the first redistribution layer.

16. The RF semiconductor package of claim 15, further comprising a surface mount device coupled to the first redistribution layer.

17. The RF semiconductor package of claim 16, wherein the second portion of the metal plate is thermally coupled to the die for dissipation of heat generated by the die.

18. The RF semiconductor package of claim 17, wherein the metal plate is configured in a fan out land grid array pattern.

19. The RF semiconductor package of claim 18, wherein the first portion of the metal plate is physically separate from the second portion of the metal plate to electrically isolate the transmission line from the ground plane.

20. The RF semiconductor package of claim 19, further comprising a plurality of signal vias and a plurality of ground vias.

21. The RF semiconductor package of claim 20, wherein the first portion of the metal plate is configured as a plurality of RF signal connection pads.

22. The RF semiconductor package of claim 21, further comprising a thermal interface material positioned between the die and the second portion of the metal plate to adhere the die to the metal plate.

23. The RF semiconductor package of claim 22, wherein the RF semiconductor package is integrated into one of a mobile phone, a mobile communication device, a pager, a personal digital assistant, a personal information manager, a mobile hand-held computer, a laptop computer, a wireless device, or a wireless modem.

24. A method of forming a semiconductor package, the method comprising:
attaching a semiconductor die to a metal support plate with a thermal interface material that thermally couples the semiconductor die to the metal support plate;
encapsulating the semiconductor die and the metal support plate with a molding material;
separating the metal support plate into a first portion and a second portion physically separate from the first portion;
forming a second redistribution layer on the surface of the molding material;
forming a second mold layer on the surface of the molding material;
forming a first redistribution layer on a surface of the second mold layer;
forming a plurality of first vias extending vertically from the first portion of the metal support plate to the first redistribution layer and coupling the plurality of first vias to the first redistribution layer; and
forming a plurality of second vias extending vertically from the second portion of the metal support plate to the second redistribution layer and coupling the plurality of second vias to the second redistribution layer.

25. The method of claim 24, further comprising filling a gap between the first portion of the metal support plate and the second portion of the metal support plate with a dielectric material.

26. The method of claim 25, further comprising forming a fan out land grid array pattern on a bottom surface of the metal support plate.

27. The method of claim 26, further comprising integrating the semiconductor die and the metal support plate into one of a mobile phone, a mobile communication device, a pager, a personal digital assistant, a personal information manager, a mobile hand-held computer, a laptop computer, a wireless device, or a wireless modem.

28. A method of forming a RF semiconductor package, the method comprising:
attaching a semiconductor die to a support plate to thermally couple the semiconductor die to the support plate;
patterning the support plate into a first portion and a second portion electrically isolated from the first portion;
forming a signal via extending vertically from the first portion of the support plate;
forming a ground via extending vertically from the second portion of the support plate, the ground via electrically isolated from the signal via and wherein a proximity of the ground via to the signal via capacitively couples the ground via to the signal via;
forming a first redistribution layer above the first portion of the support plate and coupled to the signal via; and
forming a second redistribution layer above the second portion of the support plate and coupled to the ground via, wherein a proximity of the second redistribution layer to the first redistribution layer capacitively couples the second redistribution layer to the first redistribution layer.

29. The method of claim 28, further comprising forming a plurality of signal vias and a plurality of ground vias.

30. The method of claim 29, further comprising coupling the first redistribution layer to the semiconductor die and coupling the second redistribution layer to the semiconductor die.
